(19) United States
(12) Patent Application Publication
(10) Pub. No.: US 2025/0380547 A1
(43) Pub. Date: Dec. 11, 2025

(54) DISPLAY DEVICE

(71) Applicant: Samsung Display Co., LTD., Yongin-si (KR)

(72) Inventors: Dong Hee SHIN, Yongin-si (KR); Sun Kwun SON, Yongin-si (KR); Na Hyeon CHA, Yongin-si (KR)

(21) Appl. No.: 19/030,594

(22) Filed: Feb. 20, 2025

(30) Foreign Application Priority Data
Jun. 10, 2024 (KR) 10-2024-0075034

(51) Int. Cl. H10H 29/37; H10H 29/49; H10H 29/80

(52) U.S. Cl. CPC H10H 29/37; H10H 29/49; H10H 29/8322

(57) ABSTRACT

The present disclosure relates to a display device, and the display device according to an embodiment includes a plurality of first electrodes on a substrate, a pixel defining layer between respective ones of the plurality of first electrodes and covering edges of the plurality of first electrodes, a metal wire on the pixel defining layer, and a second electrode on the light emitting layer and the metal wire and electrically connected to the metal wire.

### CROSS-REFERENCE TO RELATED APPLICATION

The present application claims priority to and the benefit of Korean Patent Application No. 10-2024-0075034, filed on Jun. 10, 2024, in the Korean Intellectual Property Office, the entire content of which is hereby incorporated by reference.

### BACKGROUND

### 1. Field

Embodiments of this disclosure relate to a display device.

### 2. Description of the Related Art

Display devices such as liquid crystal displays (LCD) and organic light emitting diode displays (OLED displays) include a display panel including a plurality of pixels capable of displaying images. Each pixel may include a first electrode that receives a data signal, a plurality of transistors and one or more capacitors that transmit the data signal to the first electrode, and a second electrode opposing the first electrode. At least one layer may be between the first electrode and the second electrode.

The second electrode may be provided across a plurality of pixels and may transmit a constant voltage to each pixel. If there is a voltage drop in the common voltage transmitted by the second electrode, unevenness may occur in the luminance of the image displayed by the display panel. For example, as the display device becomes larger, luminance unevenness caused by a voltage drop in the second electrode may become more noticeable.

Recently, a method of connecting to wiring using a laser drilling process has been actively used as a process to lower the resistance (e.g., electrical resistance) of the second electrode. However, there is a problem in that a pixel aperture ratio is lowered as space is needed to form through holes using a laser.

### SUMMARY

Embodiments of the present disclosure provide a display device that may reduce a drop in voltage transmitted by a second electrode by bringing a metal wire into contact with the second electrode without reducing a pixel aperture ratio.

The display device according to an embodiment includes a plurality of first electrodes on a substrate, a pixel defining layer between respective ones of the plurality of first electrodes and that covers edges of the plurality of first electrodes, a metal wire on the pixel defining layer, and a second electrode on a light emitting layer and the metal wire and electrically connected to the metal wire.

In the display device according to an embodiment, the metal wire may include a plurality of first parts that extend in a first direction on a plane, and a plurality of second parts that extend along a second direction that crosses the first direction, and the plurality of first parts and the plurality of second parts may be connected to each other.

In the display device according to an embodiment, the second electrode may directly contact top and side surfaces of the metal wire.

In the display device according to an embodiment, the metal wire may have a thickness of 3000 Å or more in a direction perpendicular (e.g., substantially perpendicular) to the substrate.

In the display device according to an embodiment, the metal wire may overlap the pixel defining layer in a direction perpendicular (e.g., substantially perpendicular) to the substrate.

In the display device according to an embodiment, the metal wire may include Cu, Al, or a combination thereof.

In the display device according to an embodiment, the second electrode may include Mg, Ag, an alloy material thereof, or a combination thereof.

The display device according to an embodiment may further include a first adhesive member between the metal wire and the light emitting layer.

In the display device according to an embodiment, the first adhesive member may be adhered to a lower surface of the metal wire.

In the display device according to an embodiment, a planar shape of the metal wire and a planar shape of the first adhesive member may be the same.

The display device according to an embodiment may include a plurality of first electrodes on a substrate, a pixel defining layer between respective ones of the plurality of first electrodes and that cover edges of the plurality of first electrodes, the light emitting layer above the plurality of first electrodes, a metal wire above the pixel defining layer, a second electrode above the light emitting layer and the metal wire and electrically connected to the metal wire, the first adhesive member between the metal wire and the light emitting layer, and a second adhesive member between the metal wire and the second electrode.

In a display device according to an embodiment, the metal wire may include a plurality of first parts that extend in a first direction on a plane, and a plurality of second parts that extend in a second direction that crosses the first direction, and the plurality of first parts and the plurality of second parts may be connected to each other.

In the display device according to an embodiment, the second electrode may directly contact a side surface of the metal wire.

In the display device according to an embodiment, the metal wire may have a thickness of 3000 Å or more in a direction perpendicular (e.g., substantially perpendicular) to the substrate.

In the display device according to an embodiment, the metal wire may overlap the pixel defining layer in a direction perpendicular (e.g., substantially perpendicular) to the substrate.

In the display device according to an embodiment, the metal wire may include Cu, Al, or a combination thereof.

In the display device according to an embodiment, an adhesive force of the second adhesive member may be smaller than an adhesive force of the first adhesive member.

In the display device according to an embodiment, the second adhesive member may include an insulating material (e.g., an electrically insulating material) and/or a metal material.

In the display device according to an embodiment, the first adhesive member may be adhered to a lower surface of the metal wire, and the second adhesive member may be adhered to an upper surface of the metal wire.

In the display device according to an embodiment, a planar shape of the metal wire, a planar shape of the first adhesive member, and a planar shape of the second adhesive member may all be the same (e.g., substantially the same).

According to embodiments, a voltage drop of ELVSS transmitted by the second electrode may be reduced by bringing the metal wire into contact with the second electrode without reducing the pixel aperture ratio.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a block diagram of an electronic device according to an embodiment.

FIG. 2 shows schematic diagrams of electronic devices according to various embodiments.

FIG. 3 is a plan view of a display area of a display device according to an embodiment.

FIG. 4 is an enlarged view of area S in FIG. 3.

FIG. 5 is a cross-sectional view of one pixel of a display device according to an embodiment.

FIG. 6 to FIG. 8 are cross-sectional views showing a method of manufacturing a display device according to an embodiment.

FIG. 9 to FIG. 11 are cross-sectional views showing a method of manufacturing a display device according to another embodiment.

### DETAILED DESCRIPTION

Hereinafter, with reference to the attached drawings, various embodiments of the present disclosure will be described in more detail so that those skilled in the art may easily implement the subject matter of the present disclosure. The subject matter of the present disclosure may be implemented in many different forms and is not limited to the embodiments described herein.

In order to clearly explain the subject matter of the present disclosure, parts that are not relevant to the description are omitted, and identical or similar components are assigned the same reference numerals throughout the specification.

The attached drawings are intended only to facilitate understanding of the embodiments disclosed herein, and it is to be understood that the technical ideas disclosed herein are not limited by the attached drawings and include all modifications, equivalents, or substitutions that are within the scope of the ideas and technology of the present disclosure.

The size and thickness of each component shown in the drawings may be arbitrarily shown for convenience of explanation, so the present disclosure is not necessarily limited to that which is shown. In the drawings, the thickness may be enlarged to clearly express various layers and areas. And in the drawings, for convenience of explanation, the thickness of some layers and regions may be exaggerated.

If (e.g., when) a part of a layer, film, region, or plate is said to be “above” or “on” another part, this includes not only cases where it is “directly above” another part, but also cases where there is another part in between. If (e.g., when) an element is referred to as being “directly on” another element, there are no intervening elements present. In embodiments, being “above” or “on” a reference part means being above or below the reference part, and does not necessarily mean being “above” or “on” it in the direction opposite to gravity.

Throughout the specification, if (e.g., when) a part is said to “include” a certain component, this means that it may further include other components rather than excluding other components, unless specifically stated to the contrary.

Throughout the specification, if (e.g., when) reference is made to “on a plane,” or a “plan view” this means if (e.g., when) the target part is viewed from above, and if (e.g., when) reference is made to “in cross-section,” this means if (e.g., when) a cross-section of the target part is cut vertically and viewed from the side.

Throughout the specification, the term “connected” does not mean only that two or more components are directly connected, but may also mean that two or more components are indirectly connected through another component, that two or more components are electrically connected as well as physically connected, or that two or more components are referred to by different names depending on their location or function but are unitary.

Hereinafter, various embodiments and modifications will be described in detail with reference to the drawings.

A display device according to an embodiment may be applied to various electronic devices. An electronic device according to an embodiment may include the display device, and may further include modules or devices having additional functions other than the display device.

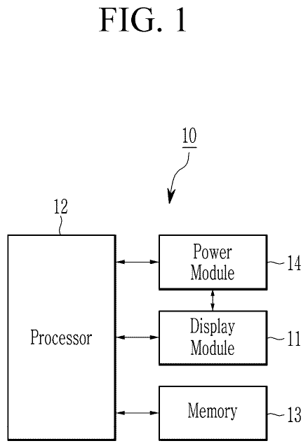

FIG. 1 is a block diagram of an electronic device according to an embodiment. Referring to FIG. 1, the electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for operations of the processor 12 or the display module 11. When the processor 12 executes an application stored in the memory 15, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 10.

At least one of components of the electronic device 10 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 10 that are not part of the display device.

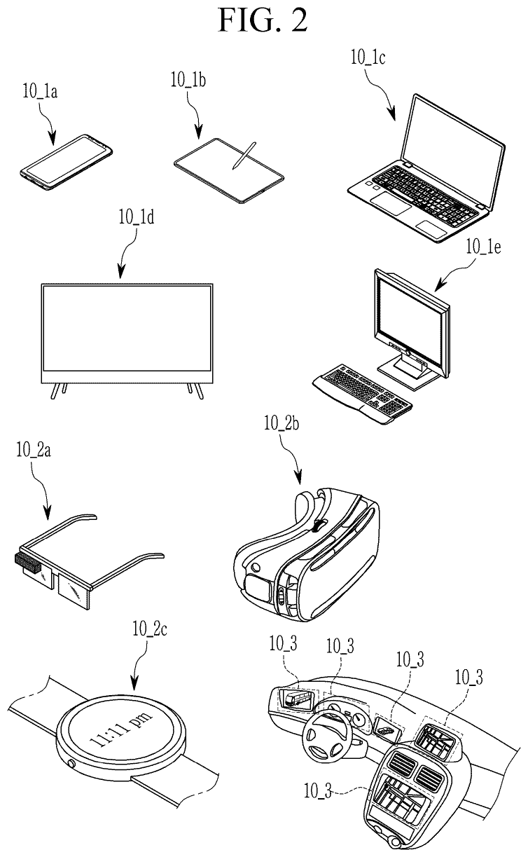

FIG. 2 shows schematic diagrams of electronic devices according to various embodiments.

Referring to FIG. 2, various electronic devices with the display device according to the embodiments may include not only image display electronic devices such as smartphones 10_1a, tablet PCs 10_1b, laptops 10_1c, TVs 10_1d, desktop monitors 10_1e, but also wearable electronic devices with display modules such as smart glasses 10_2a, head-mounted displays 10_2b, smart watches 10_2c, as well as automotive electronic devices with display modules 10_3 such as those placed on car dashboards, center fascias, CID (Center Information Display), room mirror displays, and so on.

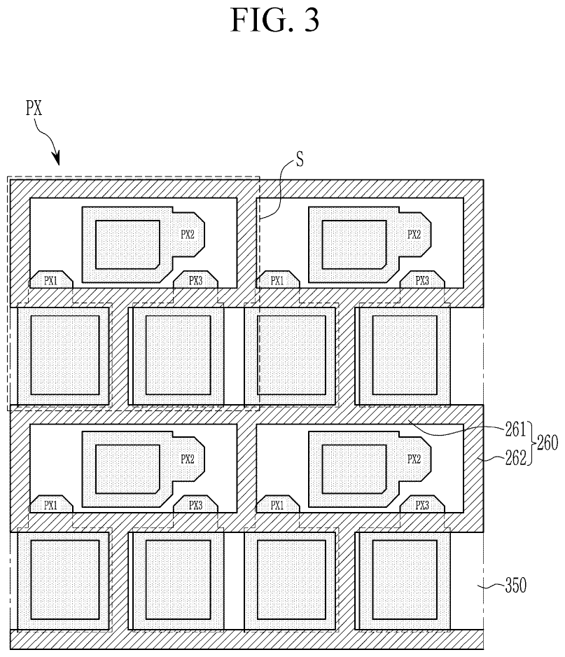

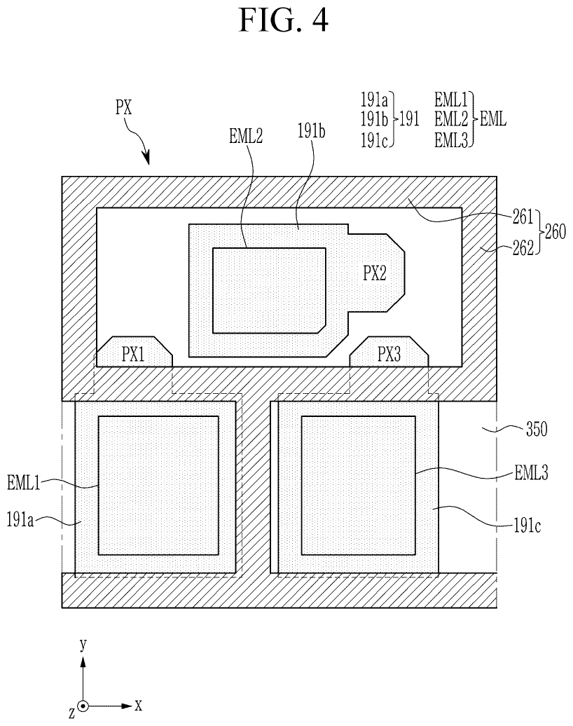

FIG. 3 is a plan view of a display area of a display device according to an embodiment. FIG. 4 is an enlarged view of area S in FIG. 3.

Referring to FIG. 3, a display device according to an embodiment includes a display area, and the display area may include a plurality of pixels PX, which are units capable of displaying an image. The plurality of pixels PX may be provided in a roughly matrix form on a plane in the display area, but they are not limited thereto and may be provided repeatedly according to various suitable rules.

Referring to FIGS. 1-2, in the display device according to an embodiment, each pixel PX may include at least one sub-pixel. For example, the pixel PX may include a first sub-pixel PX1, a second sub-pixel PX2, and a third sub-pixel PX3. In the following embodiment, if (e.g., when) naming the first sub-pixel PX1, the second sub-pixel PX2, and the third sub-pixel PX3 collectively, they may be referred to as the sub-pixel PX1, PX2, PX3 and/or sub-pixels PX1, PX2, PX3.

The sub-pixels PX1, PX2, PX3 included in each pixel PX may display light of different colors. For example, the sub-pixels PX1, PX2, PX3 may display basic colors such as red, green, and blue, respectively. The display device may display images of various suitable colors by combining various suitable luminance of different basic colors displayed by the sub-pixels PX1, PX2, PX3. Each of the sub-pixels PX1, PX2, PX3 may include emission areas EML1, EML2, EML3, respectively.

According to an embodiment, each sub-pixel PX1, PX2, PX3 may include a first electrode 191a, 191b, 191c, respectively, that receives a data signal including brightness information of the light displayed, and a plurality of transistors that are electrically connected to it. The first electrodes 191a, 191b, 191c are on the same layer on the substrate and may include the same material.

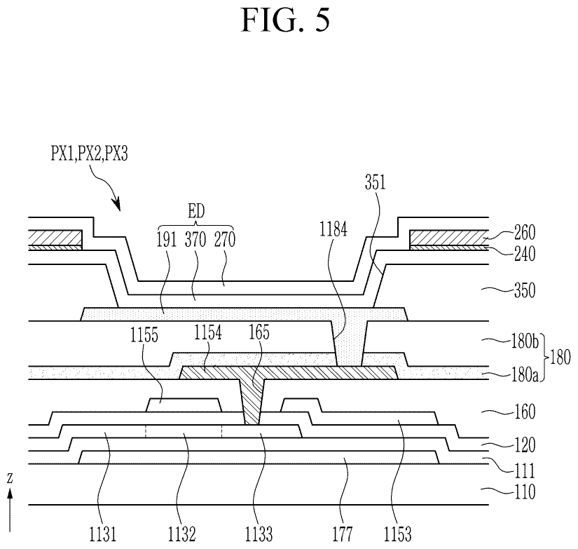

According to an embodiment, each of the first electrodes 191a, 191b, 191c may be electrically connected to a transistor provided in the sub-pixels PX1, PX2, PX3, respectively, through an aperture (e.g., opening 1184 in FIG. 5), which is a hole provided in at least one insulating layer (e.g., electrically insulating layer) between the substrate (e.g., substrate 110 in FIG. 5) and the first electrodes 191a, 191b, 191c.

According to an embodiment, each of the first electrodes 191a, 191b, 191c may overlap the light emitting regions EML1, EML2, EML3, respectively, in the third direction (z direction). In the following embodiments, the first electrodes 191a, 191b, 191c may be referred to as the first electrode 191 and/or a plurality of first electrodes 191 and the light emitting regions EML1, EML2, EML3 may collectively or respectively be referred to as the light emitting region EML.

Referring to FIGS. 1-2, a pixel defining layer 350 may be between a plurality of first electrodes 191 in a display device according to an embodiment. The pixel defining layer 350 may cover edges of the plurality of first electrodes 191.

The pixel defining layer 350 may be a structure that defines (or partitions) the light emitting region EML of each of the sub-pixels PX1, PX2, PX3, but is not limited thereto.

According to an embodiment, a metal wire 260 may be on the pixel defining layer 350. According to an embodiment, the metal wire 260 may be on the pixel defining layer 350 so as not to overlap the light emitting region EML. According to an embodiment, the metal wire 260 may overlap the pixel defining layer 350 in the third direction (z direction).

According to an embodiment, the metal wire 260 may include a plurality of first parts 261 that extend in a first direction (x direction) on a plane, and a plurality of second parts 262 that extend in a second direction (y direction) that intersects or crosses the first direction (x direction). According to an embodiment, the plurality of first parts 261 and the plurality of second parts 262 may be connected to each other. For example, the plurality of first parts 261 and the plurality of second parts 262 included in the metal wire 260 may be integrally provided and connected to each other.

According to an embodiment, the metal wire 260 may be provided across a plurality of pixels. The metal wire 260 may be provided entirely on the display area of the substrate 110 (e.g., may be provided on the entire display area of the substrate 110).

FIG. 5 is a cross-sectional view of one pixel of a display device according to an embodiment.

Referring to FIG. 5, the display device may include a plurality of conductive layers (e.g., electrically conductive layers) and a plurality of insulating layers (e.g., electrically insulating layers) on the substrate 110.

According to an embodiment, a buffer layer 111 may be on the substrate 110. The substrate 110 may be formed of various suitable materials such as glass, metal, and/or plastic including polyethylene terephthalate PET, polyethylene naphthalate PEN, and/or polyimide.

According to an embodiment, the buffer layer 111 may prevent or reduce diffusion of metal atoms or impurities from the substrate 110. In some embodiments, the buffer layer 111 may serve to improve the flatness of the surface of the substrate 110 if (e.g., when) the surface of the substrate 110 is not uniform. The buffer layer 111 may be formed using a silicon compound. For example, the buffer layer 111 may include silicon oxide SiOx, silicon nitride SiNx, silicon oxynitride SiOxNy, silicon oxycarbide SiOxCy, silicon carbonitride SiCxNy, etc. These may be used alone or in combination with each other. The buffer layer 111 may have a single-layer structure or a multilayer structure containing a silicon compound. For example, the buffer layer 111 may be provided on the substrate 110 in a single-layer structure or a multilayer structure including a silicon oxide layer, a silicon nitride layer, a silicon oxynitride layer, a silicon oxycarbide layer, and/or a silicon carbonitride layer.

According to an embodiment, a first conductive layer (e.g., a first electrically conductive layer) including a light blocking pattern 177 may be between the substrate 110 and the buffer layer 111.

According to an embodiment, a semiconductor layer including a channel region 1132 and conductive regions 1131 and 1133 (e.g., electrically conductive regions 1131 and 1133) on both sides (e.g., two opposing sides) of the channel region 1132 may be on the buffer layer 111. The conductive region 1131 on one side of one channel region 1132 may be a source region, and the conductive region 1133 on the other side may be a drain region, and vice versa. The source region and drain region may be referred to as a source electrode and a drain electrode, respectively.

According to an embodiment, a first insulating layer 120 (e.g., a first electrically insulating layer 120) may be on the semiconductor layer.

According to an embodiment, a second conductive layer (e.g., a second electrically conductive layer) including a gate electrode 1155 and a lower electrode 1153 may be on the first insulating layer 120. The gate electrode 1155 may overlap the channel region 1132 in the third direction (z direction). The gate electrode 1155 may be electrically connected to the lower electrode 1153 and may be provided as one body.

The channel region 1132, the conductive regions 1131 and 1133, and the gate electrode 1155 may together form one transistor.

A second insulating layer 160 (e.g., a second electrically insulating layer 160) may be on the gate electrode 1155 and the lower electrode 1153.

A third conductive layer (e.g., a third electrically conductive layer) including an upper electrode 1154 may be on the second insulating layer 160.

The upper electrode 1154 may provide a capacitor by overlapping the lower electrode 1153 with the second insulating layer 160 interposed therebetween. The lower electrode 1153 may also overlap the light blocking pattern 177 with the first insulating layer 120 interposed therebetween.

The upper electrode 1154 may be electrically connected to the conductive region 1133 of the transistor through an opening 165 provided in the second insulating layer 160 and the first insulating layer 120.

A third insulating layer 180 (e.g., a third electrically insulating layer 180) may be on the upper electrode 1154. The third insulating layer 180 may include a first protective layer 180a and a second protective layer 180b.

The third insulating layer 180 may include a plurality of openings 1184.

At least one selected from among the first barrier layer, the second barrier layer, and the third barrier layer may include a metal including copper (Cu), aluminum (Al), magnesium (Mg), silver (Ag), gold (Au), platinum (Pt), palladium (Pd), nickel (Ni), neodymium (Nd), iridium (Ir), molybdenum (Mo), tungsten (W), titanium (Ti), chromium (Cr), tantalum (Ta), and/or their alloys, and/or metal oxides such as ITO (indium tin oxide) and/or IZO (indium zinc oxide). Each of the first conductive layer, the second conductive layer, and the third conductive layer may be made of a single layer or multilayer structure. For example, at least one selected from among the first conductive layer, the second conductive layer, and the third conductive layer may have a multilayer structure including a lower layer including titanium, a middle layer including copper, and an upper layer including ITO.

According to an embodiment, at least one selected from among the buffer layer 111, the first insulating layer 120, the second insulating layer 160, and the third insulating layer 180 may include inorganic insulating materials such as silicon nitride SiNx, silicon oxide SiOx, and/or silicon oxynitride SiON, and/or organic insulating materials such as polyimide, acrylic polymer, and/or siloxane polymer. The first protective layer 180a of the third insulating layer 180 may be made of an inorganic insulating material (e.g., an inorganic electrically insulating material), and the second protective layer 180b may be made of an organic insulating material (e.g., an organic electrically insulating material).

According to an embodiment, a fourth conductive layer (e.g., a fourth electrically conductive layer) including the first electrode 191 may be on the third insulating layer 180. The first electrode 191 may include the plurality of first electrodes 191a, 191b, and 191c shown in FIG. 4. The fourth conductive layer may include a transparent metal oxide such as indium tin oxide ITO and/or indium zinc oxide IZO. The fourth conductive layer may be made of a single layer or a plurality of layers.

According to an embodiment, the first electrode 191 on the substrate 110 may be electrically connected to the upper electrode 1154 through the opening 1184.

According to an embodiment, the pixel defining layer 350 may be on the first electrode 191. The pixel defining layer 350 may include an organic insulating material (e.g., an organic insulating material) such as polyimide, polyamide, acrylic resin, benzocyclobutene, and/or phenol resin, and/or a silica-based inorganic insulating material (e.g., a silica-based inorganic electrically insulating material.

According to an embodiment, the pixel defining layer 350 may cover the edge of the first electrode 191. In some embodiments, the pixel defining layer 350 may have a pixel opening 351 that overlaps the first electrode 191.

According to an embodiment, a light emitting layer 370 may be on the pixel defining layer 350 and the first electrode 191. For example, at least a part of the light emitting layer 370 may be on the pixel defining layer 350, and at least a part of the light emitting layer 370 may be on the first electrode 191. The light emitting layer 370 may be provided along surfaces of the pixel defining layer 350 and the first electrode 191.

According to an embodiment, at least a part of the light emitting layer 370 may be provided within the pixel opening 351 of the pixel defining layer 350 and may be in contact with the first electrode 191. The light emitting layer 370 provided within the pixel opening 351 of the pixel defining layer 350 may be referred to as a light emitting region (e.g., the light emitting region EML in FIG. 4). For example, the light emitting region EML may be defined by the pixel opening 351 of the pixel defining layer 350.

According to an embodiment, the light emitting layer 370 may include a low-molecular organic material (e.g., a low-molecular weight organic material) and/or a high-molecular organic material (e.g., high-molecular weight organic material) such as poly 3,4-ethylenedioxythiophene PEDOT. The light emitting layer 370 may further include one or more selected from among a hole injection layer HIL, a hole transporting layer HTL, an electron transporting layer ETL, and an electron injection layer EIL, and may include a plurality of layers. The light emitting layer 370 may be provided mostly within the pixel opening 351 and may include a part on the pixel defining layer 350. At least a part of the light emitting layer 370 may be formed through a deposition process.

According to an embodiment, an adhesive member 240 may be on the light emitting layer 370. For example, the adhesive member 240 may be between the metal wire 260 and the light emitting layer 370. In some embodiments, the adhesive member 240 may be adhered to a lower surface of the metal wire 260. For example, the metal wire 260 may be adhered (or fixed) to the light emitting layer 370 by the adhesive member 240.

The adhesive member 240 may contact at least a part of the light emitting layer 370 on the pixel defining layer 350. The adhesive member 240 may be directly above a region of the light emitting layer 370 that overlaps the pixel defining layer 350 in the third direction (z direction).

According to an embodiment, the adhesive member 240 may include an organic material having an adhesive component. For example, the adhesive member 240 may be made of a pressure-sensitive adhesive PSA. A pressure-sensitive adhesive may be an adhesive that acts if (e.g., when) pressure is applied to bond the adhesive to an adhesive surface. The adhesive strength of the adhesive member 240 may be affected by the amount of pressure that causes the adhesive to be applied to the adhesive surface. At this time, solvent, water, or heat may not be required to activate the adhesive member 240.

According to an embodiment, the metal wire 260 may be on the adhesive member 240. The metal wire 260 may be in direct contact with the adhesive member 240.

According to an embodiment, a planar shape of the metal wire 260 may be the same as or similar to a planar shape of the adhesive member 240. In some embodiments, an area of the metal wire 260 may be the same as or similar to an area of the adhesive member 240.

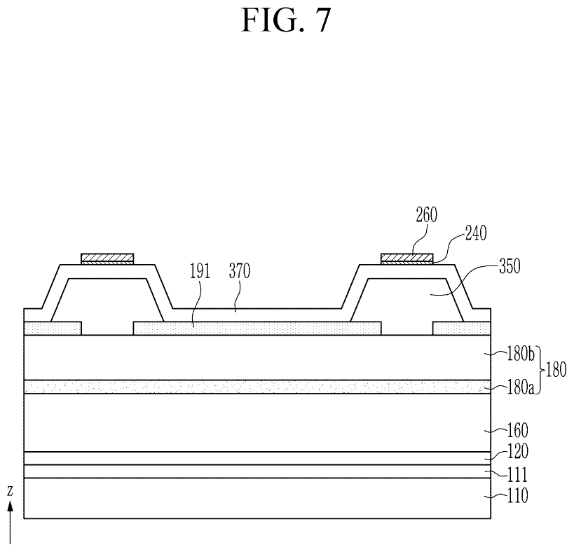

In the present disclosure, the term “adhesive member” may correspond to the “first adhesive member” which will be further described with reference to FIGS. 7-9.

As described above, in the display device according to embodiments of this disclosure, the metal wire 260 and the adhesive member 240 have the same or similar shape and/or area, allowing the metal wire 260 to be stably adhered to the light emitting layer 370.

According to an embodiment, the metal wire 260 may be made of a low-resistance material (e.g., a low electrical resistance material). For example, the metal wire 260 may include Cu, Al, or a combination thereof.

According to an embodiment, the metal wire 260 may have a set or predetermined thickness in a direction perpendicular (e.g., substantially perpendicular) to the substrate 110 (third direction (z direction)). For example, the metal wire 260 may have a thickness of about 3000 Å or more in the third direction (z direction).

As described above, in the display device according to embodiments of the present disclosure, the metal wire 260 has a thickness greater than or equal to a set or predetermined value in a direction perpendicular (e.g., substantially perpendicular) to the substrate 110, thereby securing sufficient contact area with a second electrode 270.

According to an embodiment, the second electrode 270 may be on the light emitting layer 370 and the metal wire 260. For example, the second electrode 270 may be provided along the surfaces of the light emitting layer 370 and the metal wire 260. According to an embodiment, the second electrode 270 may be electrically connected to the metal wire 260. According to an embodiment, the second electrode 270 may directly contact the top and side surfaces of the metal wire 260.

As described above, the voltage drop at the second electrode may be reduced by lowering the resistance (e.g., electrical resistance) of the second electrode 270 as it contacts the metal wire 260.

The second electrode 270 may be provided a single conductor (e.g., a single electrical conductor) across a plurality of pixels. The second electrode 270 may be provided entirely on the display area of the substrate 110 (e.g., an entire display area of the substrate 110).

The second electrode 270 may include a metallic material including silver (Ag), magnesium (Mg), and/or their alloy materials (e.g., magnesium-silver (Mg—Ag)), and/or transparent metal oxides such as ITO (indium tin oxide), IZO (indium zinc oxide), etc.

The first electrode 191, the light emitting layer 370, and the second electrode 270 of each sub-pixel PX1, PX2, PX3 may together form a light emitting diode ED, which is a light emitting element. The first electrode 191 may be an anode, and the second electrode 270 may be a cathode, but some embodiments may be the other way around.

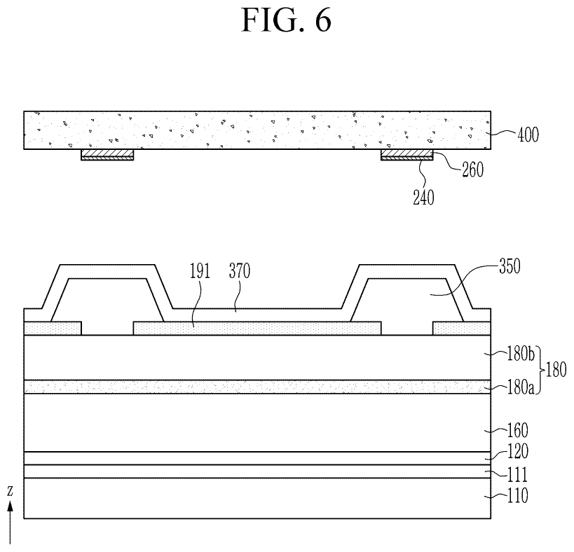

FIG. 6 to FIG. 8 are cross-sectional views showing a method of manufacturing a display device according to an embodiment. FIG. 6 to FIG. 8 may show structures of intermediate states in the process of forming a display device. In addition to the configurations shown in FIGS. 4 to 6, the display device may include other configurations through subsequent processes. Detailed description of parts that have already been described may not be repeated, and parts that have not been explained will be explained in more detail.

Referring to FIG. 6, in the method of manufacturing a display device according to an embodiment, a metal wire 260 may be patterned and formed on a carrier substrate 400. For example, the metal wire 260 may be formed using a photolithography process. The carrier substrate 400 layer is patterned in a linear form having a constant width in a direction parallel (e.g., substantially parallel) to the substrate 110 (for example, the first direction (x direction) or the second direction (y direction) in FIG. 3), allowing the metal wire 260 to be formed. For example, the metal wire 260 may include a plurality of first parts (e.g., a first part 261 in FIG. 3) that extend in a first direction (x direction) on a plane, and a plurality of second parts (e.g., second parts 262 in FIG. 3) that extend along a second direction (y direction) that intersects or crosses the first direction (x direction). In some embodiments, the plurality of first parts and the plurality of second parts may be formed to be connected to each other.

According to an embodiment, the metal wire 260 may be patterned to have a set or predetermined thickness in the third direction (z direction). For example, the metal wire 260 may have a thickness of 3000 Å or more in the third direction (z direction).

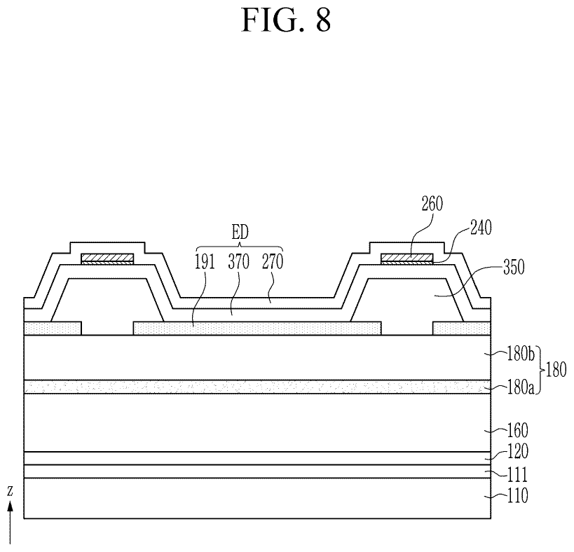

As described above, in the display device according to the present disclosure, the metal wire 260 has a thickness greater than or equal to a set or predetermined value in the third direction (z direction), and as will be further described with reference to FIG. 8, it may have sufficient contact area with the second electrode 270.

According to an embodiment, the metal wire 260 may be patterned and formed on the lower surface of the carrier substrate 400 facing the light emitting layer 370. For example, the metal wire 260 may be on the lower surface of the carrier substrate 400 to be transferred onto the light emitting layer 370.

The carrier substrate 400 is a rigid substrate and may be one selected from among a glass substrate, a quartz substrate, a glass ceramic substrate, and a crystalline glass substrate. The carrier substrate 400 may be removed after the metal wire 260 is laminated (or adhered) on the light emitting layer 370.

According to an embodiment, the adhesive member 240 may be provided on the lower surface of the metal wire 260. For example, the adhesive member 240 may include an organic material including an adhesive component. According to an embodiment, the planar shape of the adhesive member 240 may be the same as or similar to the planar shape of the metal wire 260. In some embodiments, the area of the adhesive member 240 may be the same as or similar to the area of the metal wire 260.

Referring to FIG. 7, in the method of manufacturing a display device according to an embodiment, the metal wire 260 may be transferred to the light emitting layer 370. According to an embodiment, the metal wire 260 may be transferred to the light emitting layer 370 so as to overlap the pixel defining layer 350 in the third direction (z direction). According to an embodiment, the metal wire 260 may be transferred to the light emitting layer 370 so as not to overlap the pixel opening (e.g., the pixel opening 351 in FIG. 5) in the third direction (z direction).

According to an embodiment, the metal wire 260 may be transferred onto the light emitting layer 370 by contacting a patterned carrier substrate (e.g., the carrier substrate 400 of FIG. 6) on the light emitting layer 370. For example, as pressure is applied to adhere the adhesive member 240 to the light emitting layer 370, the metal wire 260 may be adhered (or fixed) to the light emitting layer 370 by the adhesive member 240.

In some embodiments, the adhesive strength of the adhesive member 240 may be affected by the amount of pressure that causes the adhesive to be applied to the surface. For example, the greater the pressure that causes the adhesive to be applied to the surface, the greater the adhesive strength of the adhesive member 240.

According to an embodiment, as the metal wire 260 is adhered to the light emitting layer 370, the metal wire 260 may be separated from the carrier substrate 400. After the metal wire 260 is adhered to the light emitting layer 370, the carrier substrate 400 may be removed.

Referring to FIG. 8, in the method of manufacturing a display device according to an embodiment, a second electrode 270 may be formed on the light emitting layer 370 and the metal wire 260. For example, the second electrode 270 may be formed using a printing process, a sputtering process, a chemical vapor deposition process, an atomic layer deposition process, a vacuum deposition process, a pulse laser deposition process, etc.

The second electrode 270 may include aluminum, aluminum-containing alloys, aluminum nitride, silver, silver-containing alloys, tungsten, tungsten nitride, copper, copper-containing alloys, nickel, chromium, chromium nitride, molybdenum, molybdenum-containing alloys, titanium, titanium nitride, platinum, tantalum, tantalum nitride, neodymium, scandium, strontium ruthenium, zinc oxide, indium tin oxide, tin oxide, indium oxide, gallium oxide, indium zinc oxide, and/or the like. These may be used alone or in combination with each other. In embodiments, the second electrode 270 may be formed in a single-layer structure or a multilayer structure including a metal film, an alloy film, a metal nitride film, a conductive metal oxide film, and/or a transparent conductive material film.

According to an embodiment, the second electrode 270 may be provided along the surfaces of the light emitting layer 370 and the metal wire 260. According to an embodiment, the second electrode 270 may be electrically connected to the metal wire 260. According to an embodiment, the second electrode 270 may directly contact the top and side surfaces of the metal wire 260.

According to an embodiment, the contact area between the second electrode 270 and the metal wire 260 may suitably vary depending on the area and/or thickness of the metal wire 260. For example, the greater the area and/or thickness of the metal wire 260, the greater the area in direct contact with the second electrode 270.

As described above, in the display device according to the present embodiment, the voltage drop in the second electrode 270 may be reduced by lowering the resistance (electrical resistance) by bringing the second electrode 270 into contact with the metal wire 260.

As described above, in the display device according to embodiments, the metal wire 260 has a set or predetermined thickness, thereby ensuring stable contact characteristics between the second electrode 270 and the metal wire 260.

In some embodiments, the voltage drop at the second electrode 270 may be reduced without the need for additional processes and structures, such as laser drilling of the light emitting layer for contact between the second electrode 270 and the auxiliary wiring, which may facilitate the realization of a high-resolution display device.

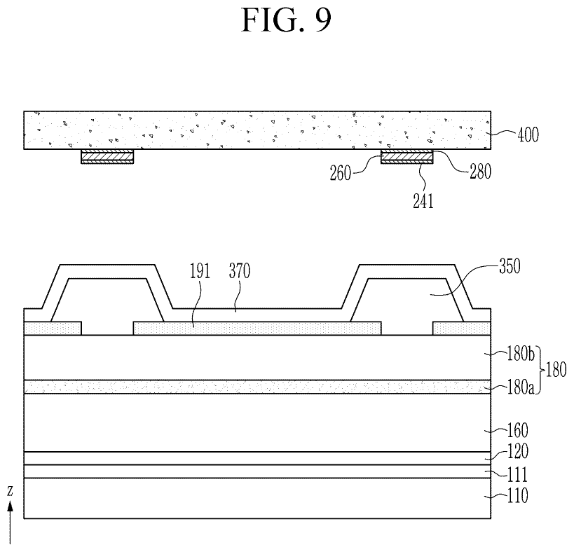

FIG. 9 to FIG. 11 are cross-sectional views showing a method of manufacturing a display device according to another embodiment. FIG. 9 to FIG. 11 may show structures of intermediate states in the process of forming a display device. In addition to the configurations shown in FIGS. 7 to 9, the display device may include other configurations through subsequent processes. Detailed description of parts that have already been described may not be repeated, and parts that have not been described above will be described in detail.

Referring to FIG. 9, in the method of manufacturing a display device according to an embodiment, a metal wire 260 may be patterned and formed on the carrier substrate 400. For example, the metal wire 260 may be formed using a photolithography process. The carrier substrate 400 layer is patterned in a linear form having a constant width in a direction parallel (e.g., substantially parallel) to the substrate 110 (for example, the first direction (x direction) or the second direction (y direction) in FIG. 3), allowing for formation of the metal wire 260. According to an embodiment, the metal wire 260 may be patterned to have a set or predetermined thickness in the third direction (z direction). For example, the metal wire 260 may have a thickness of 3000 Å or more in the third direction (z direction).

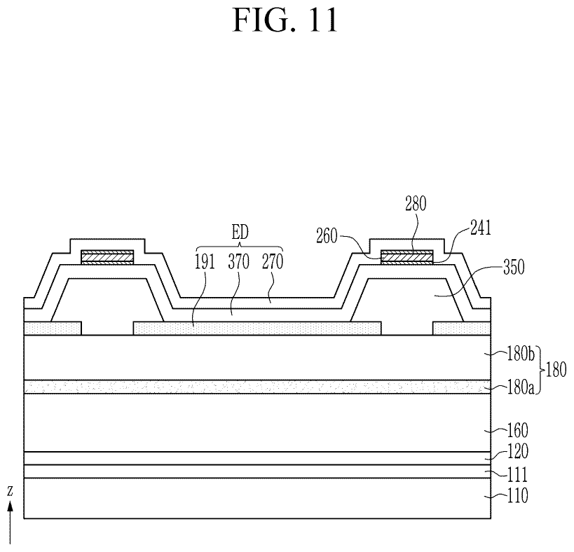

As described above, in the display device according to embodiments of the present disclosure, the metal wire 260 has a thickness greater than or equal to a set or predetermined value in the third direction (z direction), and as described with reference to FIG. 11, it may have sufficient contact area with the second electrode 270.

According to an embodiment, the metal wire 260 may be patterned and formed on the lower surface of the carrier substrate 400 facing the light emitting layer 370. For example, the metal wire 260 may be on the lower surface of the carrier substrate 400 to be transferred onto the light emitting layer 370.

The carrier substrate 400 is a rigid substrate and may be one selected from among a glass substrate, a quartz substrate, a glass ceramic substrate, and a crystalline glass substrate. The carrier substrate 400 may be removed after all components of the display device are stacked. In some embodiments, the carrier substrate 400 may be removed after the metal wire 260 is laminated (or adhered) on the light emitting layer 370.

According to an embodiment, a first adhesive member 241 may be provided on the lower surface of the metal wire 260. For example, the first adhesive member 241 may be adhered to the lower surface of the metal wire 260.

According to an embodiment, the first adhesive member 241 may include an organic material including an adhesive component. According to an embodiment, the planar shape of the first adhesive member 241 may be the same as or similar to the planar shape of the metal wire 260. In some embodiments, the area of the first adhesive member 241 may be the same or similar to the area of the metal wire 260.

According to an embodiment, a second adhesive member 280 may be provided on the upper surface of the metal wire 260. For example, the second adhesive member 280 may be adhered to the upper surface of the metal wire 260. The second adhesive member 280 may be a layer for separating the metal wire 260 from the carrier substrate 400.

According to an embodiment, the adhesive force of the second adhesive member 280 may be lower than that of the first adhesive member 241. For example, the second adhesive member 280 may include an insulating material (e.g., an electrically insulating material) and/or a metal material. For example, the second adhesive member 280 may include at least one selected from among SiOx, SiNx, Ti, and/or Mo.

According to an embodiment, the planar shape of the metal wire 260, the planar shape of the first adhesive member 241, and the planar shape of the second adhesive member 280 may all be similar or identical. According to an embodiment, the area of the metal wire 260, the area of the first adhesive member 241, and the area of the second adhesive member 280 may all be similar or the same.

As described above, in the display device according to this embodiment, the size and/or area of the metal wire 260 and the first adhesive member 241 are the same, thereby ensuring stable contact characteristics between the metal wire 260 and the light emitting layer 370.

As described above, in the display device according to this embodiment, the size and/or area of the metal wire 260 and the second adhesive member 280 are the same, thereby ensuring stable contact characteristics between the carrier substrate 400 and the metal wire 260 before the metal wire 260 is adhered to the light emitting layer 370.

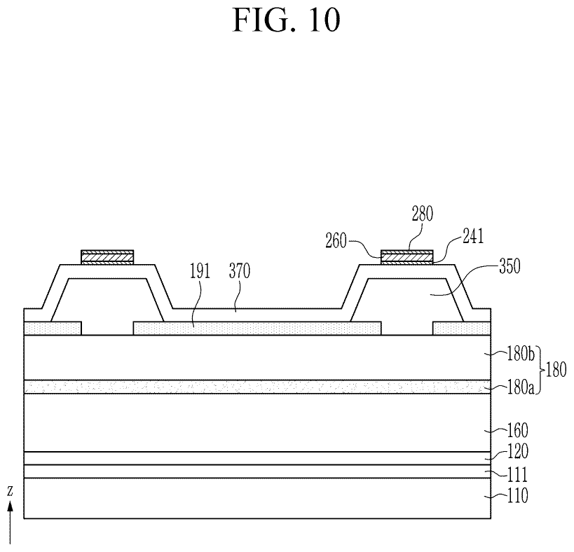

Referring to FIG. 10, in the method of manufacturing a display device according to an embodiment, the metal wire 260 may be transferred to the light emitting layer 370. According to an embodiment, the metal wire 260 may be transferred to the light emitting layer 370 so as to overlap the pixel defining layer 350 in the third direction (z direction).

According to an embodiment, the metal wire 260 may be transferred to the light emitting layer 370 by contacting a patterned carrier substrate (e.g., carrier substrate 400 of FIG. 9) on the light emitting layer 370. For example, as pressure is applied to adhere the first adhesive member 241 to the light emitting layer 370, the metal wire 260 may be adhered (or fixed) to the light emitting layer 370 by the first adhesive member 241.

In some embodiments, the adhesive strength of the first adhesive member 241 may be affected by the amount of pressure that causes the adhesive to be applied to the surface. For example, the greater the pressure for applying the adhesive to the surface, the greater the adhesive strength of the first adhesive member 241.

According to an embodiment, as the metal wire 260 is adhered to the light emitting layer 370, and the metal wire 260 may be separated from the carrier substrate 400.

As described above with reference to FIG. 9, the adhesive force of the second adhesive member 280 is lower than that of the first adhesive member 241, so that if (e.g., when) the metal wire 260 contacts the light emitting layer 370, the metal wire 260 may be easily separated from the carrier substrate 400.

According to an embodiment, the carrier substrate 400 may be removed after the metal wire 260 is adhered to the light emitting layer 370.

Referring to FIG. 11, in the method of manufacturing a display device according to an embodiment, a second electrode 270 may be formed on the light emitting layer 370 and the metal wire 260. For example, the second electrode 270 may be formed using a printing process, a sputtering process, a chemical vapor deposition process, an atomic layer deposition process, a vacuum deposition process, a pulse laser deposition process, etc.

In some embodiments, the second electrode 270 may be formed along the surfaces of the light emitting layer 370, the metal wire 260, and the second adhesive member 280. According to an embodiment, the second electrode 270 may be electrically connected to the metal wire 260. According to an embodiment, the second electrode 270 may directly contact the side of the metal wire 260.

According to an embodiment, the contact area between the second electrode 270 and the metal wire 260 may suitably vary depending on the thickness of the metal wire 260 in the third direction (z direction). For example, the greater the thickness of the metal wire 260 in the third direction (z direction), the greater the area in direct contact with the second electrode 270.

As described above, in the display device according to the present embodiment, the voltage drop in the second electrode 270 may be reduced by lowering the resistance (e.g., electrical resistance) by bringing the second electrode 270 into contact with the metal wire 260.

As described above, in the display device according to embodiments, the metal wire 260 has a set or predetermined thickness, thereby ensuring stable contact characteristics between the second electrode 270 and the metal wire 260.

In some embodiments, the voltage drop at the second electrode 270 may be reduced without the need for additional processes and structures, such as laser drilling of the light emitting layer for contact between the second electrode 270 and the auxiliary wiring, which may facilitate the realization of a high-resolution display device.

An electronic device may include the display device according to embodiments of the present disclosure. The electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

Although embodiments of the present disclosure have been described in detail above, the scope of the present disclosure is not limited thereto, and various suitable modifications and improvements made by those skilled in the art using the basic concepts of the present disclosure, which are defined in the following claims, are also possible.

### DESCRIPTION OF AT LEAST SOME OF THE SYMBOLS

110: substrate
111: buffer layer
120: first insulating layer
160: second insulating layer
180: protective layer
350: pixel defining layer
191, 191a, 191b, 191c: first electrode
270: second electrode
370: light emitting layer
240: adhesive member
241: first adhesive member
260: metal wire
280: second adhesive member

What is claimed is:

1. A display device, comprising:
a plurality of first electrodes on the substrate;
a pixel defining layer between respective ones of the plurality of first electrodes and covering edges of the plurality of first electrodes;
a light emitting layer on the plurality of first electrodes;
a metal wire on the pixel defining layer, and
a second electrode on the light emitting layer and the metal wire and electrically connected to the metal wire.

2. The display device as claimed in claim 1, wherein:
the metal wire comprises a plurality of first parts that extend in a first direction on a plane, and a plurality of second parts that extend along a second direction that crosses the first direction, and
the plurality of first parts and the plurality of second parts are connected to each other.

3. The display device as claimed in claim 1, wherein:
the second electrode is in direct contact with top and side surfaces of the metal wire.

4. The display device as claimed in claim 1, wherein:
the metal wire has a thickness of 3000 Å or more in a direction perpendicular to the substrate.

5. The display device as claimed in claim 1, wherein:
the metal wire overlaps the pixel defining layer in a direction perpendicular to the substrate.

6. The display device as claimed in claim 1, wherein:
the metal wire includes Cu, Al, or a combination thereof.

7. The display device as claimed in claim 1, wherein:
the second electrode includes Mg, Ag, an alloy material thereof, or a combination thereof.

8. The display device as claimed in claim 1, further comprising:
a first adhesive member between the metal wire and the light emitting layer.

9. The display device as claimed in claim 8, wherein:
the first adhesive member is adhered to a lower surface of the metal wire.

10. The display device as claimed in claim 8, wherein:
a planar shape of the metal wire and a planar shape of the adhesive member are the same.

11. A display device, comprising:
a plurality of first electrodes on the substrate;
a pixel defining layer between respective ones of the plurality of first electrodes and covering edges of the plurality of first electrodes;
a light emitting layer on the plurality of first electrodes;
a metal wire on the pixel defining layer;
a second electrode on the light emitting layer and the metal wire and electrically connected to the metal wire;
a first adhesive member between the metal wire and the light emitting layer; and
a second adhesive member between the metal wire and the second electrode.

12. The display device as claimed in claim 11, wherein:
the metal wire comprises a plurality of first parts that extend in a first direction on a plane, and a plurality of second parts that extend along a second direction that crosses the first direction; and
the plurality of first parts and the plurality of second parts are connected to each other.

13. The display device as claimed in claim 11, wherein:
the second electrode is in direct contact with a side of the metal wire.

14. The display device as claimed in claim 11, wherein:
the metal wire has a thickness of 3000 Å or more in a direction perpendicular to the substrate.

15. The display device as claimed in claim 11, wherein:
the metal wire overlaps the pixel defining layer in a direction perpendicular to the substrate.

16. The display device as claimed in claim 11, wherein:
the metal wire includes Cu, Al, or a combination thereof.

17. The display device as claimed in claim 11, wherein:
the adhesive force of the second adhesive member is smaller than the adhesive force of the first adhesive member.

18. The display device as claimed in claim 11, wherein:
the second adhesive member comprises an insulating material or a metal material.

19. The display device as claimed in claim 11, wherein:
the first adhesive member is adhered to the lower surface of the metal wire; and
the second adhesive member is adhered to the upper surface of the metal wire.

20. The display device as claimed in claim 11, wherein:
a planar shape of the metal wire, a planar shape of the first adhesive member, and a planar shape of the second adhesive member are all the same.

21. An electronic device comprising:
a display device, comprising:
a plurality of first electrodes on the substrate;
a pixel defining layer between respective ones of the plurality of first electrodes and covering edges of the plurality of first electrodes;
a light emitting layer on the plurality of first electrodes;
a metal wire on the pixel defining layer, and
a second electrode on the light emitting layer and the metal wire and electrically connected to the metal wire.

22. The electronic device as claimed in claim 21, wherein the electronic device is a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).
